(19) United States
(12) Patent Application Publication
(10) Pub. No.: US 2026/0184612 A1
(43) Pub. Date: Jul. 2, 2026

(54) CHEMICAL SUPPLY APPARATUS AND MAINTENANCE METHOD FOR LIQUID TREATING APPARATUS

(71) Applicant: SEMES CO., LTD., Cheonan-si (KR)

(72) Inventors: Ki Hyun KWON, Asan-si (KR); Seon Min KIM, Cheonan-si (KR); Byung Hee LEE, Hwaseong-si (KR)

(73) Assignee: SEMES CO., LTD., Cheonan-si (KR)

(21) Appl. No.: 19/423,005

(22) Filed: Dec. 17, 2025

(30) Foreign Application Priority Data
Dec. 26, 2024 (KR) 10-2024-0197645

(51) Int. Cl. C02F 1/68; C02F 103/34

(52) U.S. Cl. CPC C02F 1/68; C02F 2103/346; C02F 2303/14

(57) ABSTRACT

Disclosed is a treatment liquid supply apparatus configured to supply a chemical to a substrate processing apparatus, the apparatus including: a first tank in which a used chemical is recovered; a second tank configured to receive the chemical from the first tank; a third tank configured to receive the chemical from the second tank and connected to a main circulation line configured to supply the chemical to the apparatus; a chemical supply source configured to supply an undiluted liquid to the first tank; and a controller configured to control the tanks and supply source to perform a chemical exhaustion mode, stopping new undiluted liquid supply for a set time before maintenance liquid exchange, and exhausting residuals in the tanks.

### CROSS-REFERENCE TO RELATED APPLICATION

This application claims priority to and the benefit of Korean Patent Application No. 10-2024-0197645 filed in the Korean Intellectual Property Office on Dec. 26, 2024, the entire contents of which are incorporated herein by reference.

### TECHNICAL FIELD

The present invention relates to a chemical supply apparatus and a maintenance method for a liquid treating apparatus.

### BACKGROUND ART

Contaminants, such as particles, organic pollutants, and metal pollutants, remaining on the surface of the substrate greatly affect the characteristics and production yield of semiconductor devices. For this reason, a cleaning process of removing various pollutants attached to the surface of the substrate is very important in a semiconductor manufacturing process, and a process of cleaning the substrate is performed before and after each unit process of manufacturing a semiconductor. A process for removing such foreign substances includes a cleaning process using pure water or a chemical.

The chemical used in the substrate cleaning process may be recovered for reuse. The chemical recovered from the substrate processing unit is directly supplied to the chemical storage tank or recovered to a separate recovery storage tank and then supplied to the chemical storage tank. The recovered chemical in the chemical storage tank is supplied to the substrate processing unit and reused.

However, as the number of times of reuses of the chemical increases, there is a problem that the concentration of the chemical deviates from the reference concentration and that fine particles remain in the chemical. Accordingly, when the life time of the chemical is reached or maintained, all the chemical remaining in the tank is discharged and exchanged with a new chemical.

However, in the past, all chemicals inside the tank were drained into the wastewater line regardless of the remaining amount of chemical in the tank, causing problems, such as Environmental, Health, Safety (EHS) problems and legal regulations due to sulfur ion rise in the process using sulfuric acid.

### SUMMARY OF THE INVENTION

The present invention has been made in an effort to provide a chemical supply apparatus capable of minimizing the amount of wastewater discarded in a tank during a liquid exchange and a maintenance method for a liquid treating apparatus.

The objectives of the present disclosure are not limited thereto and other objectives not stated herein may be clearly understood by those skilled in the art from the following description.

An exemplary embodiment of the present disclosure, a treatment liquid supply apparatus for supplying a chemical to a substrate processing apparatus, the treatment liquid supply apparatus may comprising: a first tank in which a chemical used in the substrate processing apparatus is recovered; a second tank for receiving the chemical from the first tank; a third tank for receiving the chemical from the second tank and connected to a main circulation line for supplying the chemical to the substrate processing apparatus; a chemical supply source for supplying an undiluted liquid to the first tank; and a controller for controlling the tanks and the chemical supply source to perform a chemical exhaustion mode in which a supply of a new undiluted liquid from the chemical supply source is stopped for a set time before a liquid exchange for maintenance of the first tank, the second tank, and the third tank proceeds, and residual liquids in the first tank, the second tank, and the third tank are exhausted.

An exemplary embodiment of the present disclosure, a maintenance method for a liquid treating apparatus including a first tank in which a chemical used in a substrate processing apparatus is recovered, a second tank for receiving the chemical from the first tank, and a third tank for receiving the chemical from the second tank and supplying the chemical to the substrate processing apparatus, the maintenance method may comprising: a chemical exhaustion operation of stopping a supply of a new undiluted liquid from a chemical supply source for a set time before a liquid exchange of the first tank, the second tank, and the third tank proceeds, and exhausting and then draining the chemicals in the first tank, the second tank, and the third tank; a flushing operation of draining a flushing chemical after injecting and then circulating the flushing chemical into the first tank, the second tank, and the third tank; and a liquid exchange operation of supplying a new chemical to at least one of the first tank, the second tank, and the third tank and exchanging liquids.

An exemplary embodiment of the present disclosure, a treatment liquid supply apparatus for supplying a chemical to a substrate processing apparatus, the treatment liquid supply apparatus comprising: a first tank in which a chemical used in the substrate processing apparatus is recovered; a second tank for receiving the chemical from the first tank; a third tank for receiving the chemical from the second tank and connected to a main circulation line for supplying the chemical to the substrate processing apparatus; a chemical supply source for supplying an undiluted liquid to the first tank; and a controller for controlling the tanks and the chemical supply source to perform a chemical exhaustion mode in which a supply of a new undiluted liquid from the chemical supply source is stopped for a set time before a liquid exchange of the first tank, the second tank, and the third tank proceeds, and residual liquids in the first tank, the second tank, and the third tank are exhausted, wherein the controller controls all of the liquid used in the substrate processing apparatus to be treated as wastewater without recovering the liquid used in the substrate processing apparatus to the first tank in the chemical exhaustion mode, controls the third tank to be replenished with the chemical until the chemical of the second tank reaches a minimum residual level, and a remaining chemical of the second tank to be drained when the chemical of the second tank reaches the minimum residual level, and controls the third tank to be replenished with the chemical from the second tank when the chemical of the third tank falls to or below the maximum residual level, the replenishment of the chemical from the second tank to stop when the chemical of the second tank reaches the minimum residual level, the chemical to be supplied to the substrate processing apparatus until the chemical in the third tank reaches a preset level, and the third tank to be switched to a standby state for stopping the supply of the chemical to the substrate processing apparatus when the chemical in the third tank reaches the preset level.

According to the exemplary embodiment of the present invention, it is possible to minimize the amount of wastewater discarded in a tank during maintenance.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a substrate processing apparatus according to an exemplary embodiment of the present invention.

FIG. 2 is a diagram schematically illustrating an exemplary embodiment of a liquid treating chamber of FIG. 3.

FIG. 3 is a diagram illustrating a chemical supply apparatus connected to a liquid treating chamber.

FIG. 4 is a flow chart illustrating a maintenance process of the chemical supply apparatus.

FIG. 5 is a flow chart illustrating a chemical exhaustion mode of FIG. 4.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

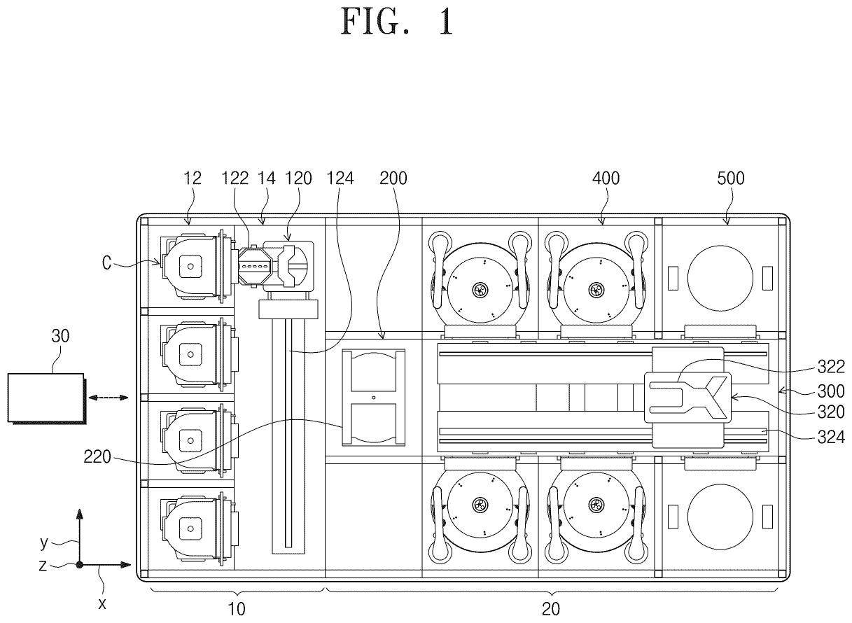

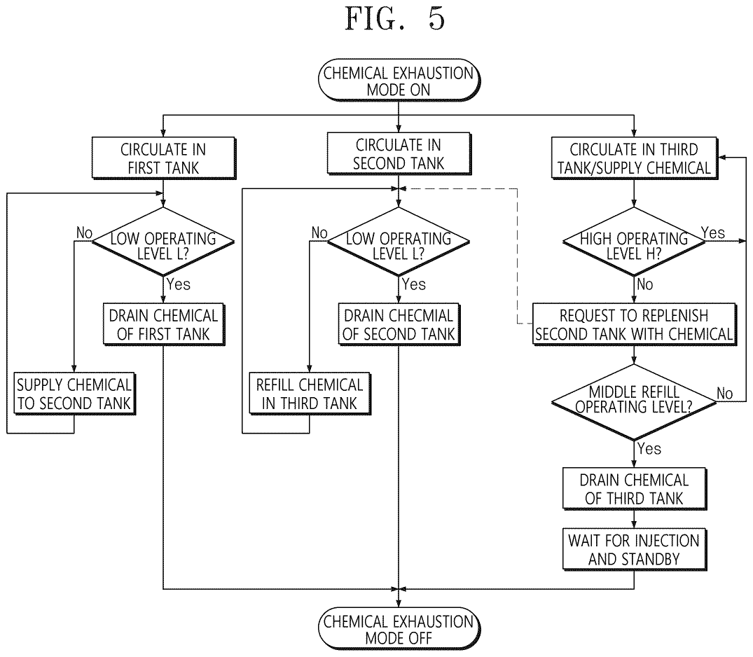

Hereinafter, an exemplary embodiment of the present invention will be described with reference to FIGS. 1 to 5.

FIG. 1 is a diagram schematically illustrating a substrate processing apparatus according to an exemplary embodiment of the present invention.

Referring to FIG. 1, a substrate processing apparatus includes an index module 10, a treating module 20, and a controller 30. When viewed from above, the index module 10 and the treating module 20 are disposed along one direction. Hereinafter, the direction in which the index module 10 and the treating module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate W from a container C in which the substrate W is accommodated to the treating module 20, and makes the substrate W, which has been completely processed in the treating module 20, be accommodated in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. The plurality of load ports 12 may be provided, and may be disposed in the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate W is placed, and the hand 122 may be provided to be movable forward and backward, rotatable about the third direction Z, and movable along the third direction Z. The plurality of hands 122 is provided while being spaced apart from each other in the up and down direction, and is capable of independently moving forward and backward.

The controller 30 may control the substrate treating apparatus. The controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The treating module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treatment process of liquid-treating the substrate W by supplying a liquid onto the substrate W. The drying chamber 500 performs a drying process for removing a liquid remaining on the substrate W. The transfer chamber 300 transfers the substrate W between the buffer unit 200, the liquid treating chamber 400, and the drying chamber 500.

The transfer chamber 300 may be provided so that a longitudinal direction is the first direction X. The buffer unit 200 may be disposed between the index module 10 and the transfer chamber 300. The liquid treating chamber 400 and the drying chamber 500 may be disposed on a side portion of the transfer chamber 300. The liquid treating chamber 400 and the transfer chamber 300 may be disposed in the second direction Y. The drying chamber 500 and the transfer chamber 300 may be disposed in the second direction Y. The buffer unit 200 may be located at one end of the transfer chamber 300.

According to an example, the liquid treating chambers 400 may be disposed on opposite sides of the transfer chamber 300, the drying chambers 500 may be disposed on opposite sides of the transfer chamber 300, and the liquid treating chambers 400 may be disposed closer to the buffer unit 200 than the drying chambers 500. At one side of the transfer chamber 300, the liquid treating chambers 400 may be provided in an array of A×B (each of A and B is 1 or a natural number larger than 1) in the first direction X and the third direction Z. Further, at one side of the transfer chamber 300, the drying chambers 500 may be provided in a number of C×D (C and D are each 1 or a natural number larger than 1) may be provided along each of the first direction X and the third direction Z. Unlike the above description, only the liquid treating chambers 400 may be provided at one side of the transfer chamber 300, and only the drying chambers 500 may be provided at the other side thereof.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward, rotatable about the third direction Z, and movable along the third direction Z. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

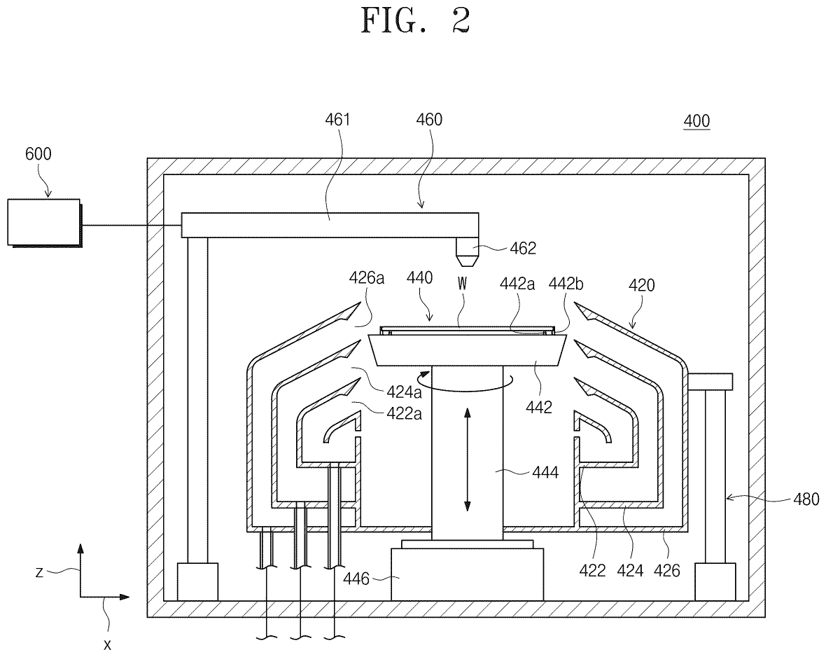

FIG. 2 is a diagram schematically illustrating an exemplary embodiment of the liquid treating chamber of FIG. 1.

Referring to FIG. 2, the liquid treating chamber 400 includes a housing 410, a cup 420, a support unit 440, a liquid injection unit 460, and a lifting unit 480.

The housing 410 may have an inner space in which the substrate W is processed. The housing 410 may have a substantially hexahedral shape. For example, the housing 410 may have a substantially rectangular parallelepiped shape. Further, an opening (not illustrated) through which the substrate W enters and exits is formed in the housing 410. Also, a door (not illustrated) for selectively opening and closing the opening may be installed in the housing 410.

The cup 420 may have a cylindrical shape with an open top. The cup 420 has a treatment space, and the substrate W is liquid-treated in the treatment space. The support unit 440 supports the substrate W in the treatment space. The liquid injection unit 460 supplies the treatment liquid onto the substrate W supported by the support unit 440. The treatment liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treatment process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a drive shaft 444. An upper surface of the support plate 442 may be provided in a generally circular shape, and may have a diameter larger than a diameter of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge portion of the support plate 442. The chuck pin 442b is provided to protrude upward from the support plate 442, and supports the side portion of the substrate W so that the substrate W does not deviate from the support unit 440 when the substrate W is rotated. The drive shaft 444 is driven by the driver 446, is connected to the center of the bottom surface of the substrate W, and rotates the support plate 442 about its central axis.

According to an example, the liquid injection unit 460 may include a nozzle 462. The nozzle 462 may discharge a treatment liquid to the substrate W. The treatment liquid may be a chemical, rinse liquid or an organic solvent. The chemical may be a chemical having strong acid or strong base properties. In addition, the liquid injection unit 460 may include a plurality of nozzles 462, and the nozzle 462 may discharge different types of treatment liquids, respectively. For example, one of the nozzles 462 may discharge a chemical, another one of the nozzles 462 may discharge the rinse liquid, and another one of the nozzles 462 may discharge the organic solvent. The liquid injection unit 460 receives a treatment liquid (chemical) from the chemical supply apparatus 600.

The present invention may be applied to a wet etching process or a cleaning process of removing a film on the surface of a substrate, and various treatment liquids may be used for this process. The treatment liquid that may be used in the present invention may include at least one material selected from hydrofluoric acid (HF), sulfuric acid (H₃SO₄), hydrogen peroxide (H₂O₂), nitric acid (HNO₃), phosphoric acid (H₃PO₄), ozone water, SC-1 solution (a mixture of ammonium hydroxide (NH₄OH), hydrogen peroxide (H₂O₂), and water) and the like, and may include treatment liquids of various materials that may be used in the substrate processing process.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 480 may move the support unit 440 in the vertical direction.

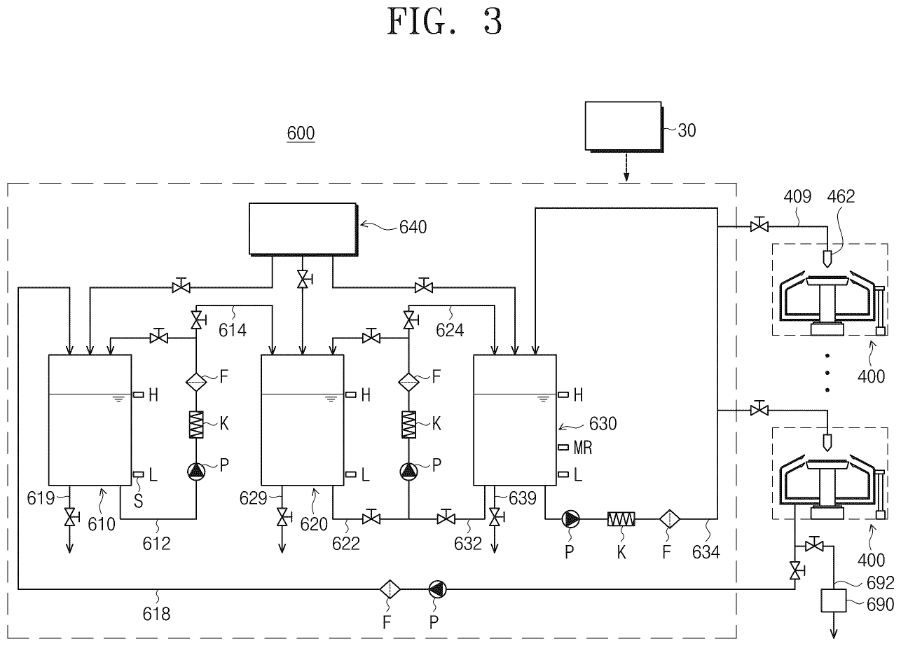

FIG. 3 is a diagram illustrating the chemical supply apparatus connected to the liquid treating chamber.

Referring to FIG. 3, the chemical supply apparatus 600 supplies a chemical used for processing a substrate to the liquid treating chamber 400.

In FIG. 3, the chemical supply apparatus 600 may be provided to supply a chemical to the plurality of liquid treating chambers 400. The liquid treating chamber 400 may perform a process of etching the film of the substrate. For example, in order to perform maintenance (liquid exchange in the tank) in the process of etching the film using sulfuric acid, all chemicals in the tank are treated as wastewater. In this process, Environmental, Health, Safety (EHS) problems may occur due to sulfur ions rising in the wastewater. Accordingly, the chemical supply apparatus of the present invention provides a maintenance (liquid exchange in a tank) system capable of minimizing the amount of wastewater discarded from the tank.

The chemical supply apparatus 600 may include a first tank 610, a second tank 620, a third tank 630, a chemical supply source 640, and a controller 30. The controller 30 may control the first tank 610, the second tank 620, the third tank 630, and the chemical supply source 640.

The first tank 610 is a recycling tank that receives and regenerates the chemical used in the liquid treating chamber 400, the second tank 620 is a sub-tank in which the temperature of the chemical received from the first tank 620 is finely adjusted, and the third tank 630 is a main tank of the chemical supply apparatus that receives the chemical from the second tank 620 and supplies the chemical to the liquid treating chamber 400.

A recovery line 618 is connected to the liquid treating chamber 400 in the first tank 610. The chemical used in the liquid treating chamber 400 may be recovered to the first tank 610 through the recovery line 618. A pump P, a heater H, and a filter F may be installed on the recovery line 618.

The first tank 610 may be replenished with a new chemical so that the chemical recovered through the recovery line 618 may be reused, and through this, the chemical concentration may be corrected. The new chemical for correcting the chemical concentration may be supplied through the chemical supply source 640.

The first tank 610 may include a first circulation line 612 and a reuse supply line 614. The first circulation line 612 circulates the chemical stored in the first tank 610. A pump P, a filter F, and a heater K may be installed on the first circulation line 612. The chemical which is regenerated in the first tank 610 may be provided to the second tank 620 through the reuse supply line 816. A first drain line 619 is provided at a lower end of the first tank 610.

The second tank 620 stores the chemical supplied from the first tank 610. A fine temperature correction of the chemical is performed in the second tank. The second tank 620 may include a second circulation line 622 and a first supply line 624. The second circulation line 622 circulates the chemical stored in the second tank 620. A pump P, a filter F, and a heater K may be installed on the second circulation line 622. The chemical of which temperature correction is completed in the second tank 620 may be provided to the third tank 630 through the first supply line 624. A second drain line 629 is provided at a lower end of the second tank 620.

The third tank 630 stores the chemical supplied from the second tank 620. The third tank 630 may include a third circulation line 632 and a supply circulation line 634. The third circulation line 632 circulates the chemical stored in the third tank 620. The third circulation line 632 may be connected to the second circulation line to use the pump P, the filter F, and the heater K installed in the second circulation line 622. The pump P, the filter F, and the heater K installed in the second circulation line may be used to internally circulate the chemical of the third tank 630. The third circulation line 632 may include a partial section of the second circulation line 622 in which the pump P, the filter F, and the heater K are installed, and the first supply line 624. A third drain line 639 is provided at a lower end of the third tank 630. The supply circulation line 634 may be provided with a pump P, a filter F, and a heater K. A supply line 409 of the liquid treating chamber 400 may be connected to the supply circulation line 634. The supply line 409 may be connected to the nozzle 462 of the liquid injection unit 460 shown in FIG. 2.

The valves installed in the first tank 610, the second tank 620, and the third tank 630 may be controlled by the controller 30.

Each of the tanks 610, 620, and 630 is provided with a plurality of water level sensors S to measure the water level by dividing the height and detecting the chemical at each height. For reference, as shown in the drawing, the water level at which the water level sensor S is operated may include, for example, H (High operating level), MR (middle refill operating level), and L (low operating level).

The treatment liquid supply source 640 may supply the chemical to the first tank 610 during the process. In addition, the treatment liquid supply source 640 may supply each tank with a flushing chemical for flushing the first tank 610, the second tank 620, and the third tank 630 when exchanging the liquid for maintenance. The flushing chemical may be the same liquid as the chemical used in the process. The chemical supply source 640 may supply the new chemical to the first tank 610 after completing the flushing mode.

The controller 30 may control the tanks 610, 620, and 630 and the chemical supply source 640.

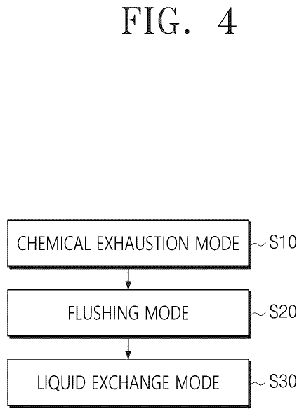

FIG. 4 is a flow chart illustrating a maintenance process of the chemical supply apparatus, and FIG. 4 is a flow chart illustrating a maintenance process of the chemical supply apparatus.

Referring to FIGS. 3 to 5, the controller 30 may control the tanks 610, 620, and 630 and the chemical supply source 640 to perform a chemical exhaustion mode S10 in which the chemical (existing chemical) stored in the first tank 610, the second tank 620, and the third tank 630 are exhausted to a preset water level and then are drained, a flushing mode S20 in which the flushing chemical is injected into each tank 610, 620, and 630 and then circulated and drained, and a liquid exchange mode S30 in which the liquid is exchanged by supplying a new chemical to the first tank 610. Maintenance in the related art includes a flushing mode for flushing the tank and a liquid exchange mode for supplying a new chemical to the tank. In the related art, when maintenance starts, all the chemical in the tank is drained regardless of the remaining amount, but in the present invention, the chemical exhaustion mode S10 is added to consume the chemical in each tank through the chemical exhaustion mode.

The controller 30 may control the liquid used in the liquid treating chamber 400 to be treated as wastewater without being recovering to the first tank 610 in the chemical exhaustion mode S10.

When the temperature correction is completed through the chemical circulation in the second tank 620 in the chemical exhaustion mode S10, the controller 30 may control the chemical to be replenished with the third tank 630 until the chemical in the second tank 620 reaches the minimum residual level L. The replenishment of the third tank 630 with the chemical is performed only when the chemical level in the third tank 630 falls to or below the maximum residual level H. The controller 30 may control the remaining chemical in the second tank 620 to be drained when the chemical in the second tank 620 reaches the minimum residual level L.

In the chemical exhaustion mode S10, when the chemical of the third tank 630 falls to or below the maximum residual level H, the controller 30 may control the second tank 620 to be replenished with the chemical, and may control the replenishment of the chemical from the second tank 620 to stop when the chemical of the second tank 620 reaches the minimum residual level L. In the chemical exhaustion mode S10, the third tank 630 circulates the chemical through the supply circulation line 634 and normally supplies the chemical to the liquid treating chamber 400. The chemical circulation and the chemical supply in the third tank 630 proceeds until the chemical of the third tank 630 reaches a preset level MR.

In the chemical exhaustion mode S10, when the chemical of the third tank 630 reaches the preset level MR, the controller 30 may control the remaining chemical to be drained. Meanwhile, the chemical used in the liquid treating chamber 400 is not directly drained through the drain line 692 branched from the recovery line 618, but is recovered to a separate cooling unit 690, and is treated as waste liquid after lowering the temperature of the high-temperature chemical to room temperature in the cooling unit 690. When the drainage of the chemical of the third tank 630 is completed, the third tank 630 is switched to an input standby and a standby state.

The controller 30 may control the chemical to be supplied to the second tank 620 until the chemical of the first tank 610 reaches the minimum residual level L in the chemical exhaustion mode S10. The controller 30 may control the remaining chemical of the first tank 610 to be drained when the chemical of the first tank 610 reaches the minimum residual level L.

The controller 30 may have different drain time points of the tanks 610, 620, and 630 in the drain mode S10. That is, the chemical may be drained in the order in which the chemical of each of the tanks 610, 620, and 630 reaches a preset water level. For example, the drain time points of the tanks 610, 620, and 630 may be in the order of the first tank 610, the second tank 620, and the third tank 630. The first tank 610 reaches the preset water level (minimum residual level L) first before other tanks because the first tank 610 is not replenished with the chemical. Since the second tank 620 receives the chemical from the first tank 620, the second tank 620 reaches secondly the preset water level (minimum residual level L) is reached. Since the third tank 630 always maintains the maximum residual level H by receiving the chemical from the second tank 620, the third tank 630 is the latest to reach the preset water level MR.

The chemical exhaustion mode S10 may be performed for a set time before liquid exchange for maintenance of the first tank 610, the second tank 620, and the third tank 630. In the chemical exhaustion mode S10, the supply of new undiluted liquid from the chemical supply source 640 is stopped, and the chemical used in the liquid treating chamber 400 is not recovered to the first tank 610 through the recovery line 618 and is treated as wastewater. Accordingly, in the chemical exhaustion mode S10, the chemical of the first tank 610, the second tank 620, and the third tank 630 may be rapidly exhausted.

As described above, the present invention may minimize the amount of waste water discarded in each tank during maintenance by exhausting the chemical of each tank as much as possible before maintenance is performed.

On the other hand, in the chemical exhaustion mode S10, the first tank 610 and the second tank 620 may exhaust the chemical until the chemical reaches the minimum residual level of L (low operating level), and the third tank 630 may exhaust the chemical until the chemical reaches the MR (the middle refill operating level) corresponding to the middle residual level. For reference, in the case of the third tank 630, a system down may occur when the chemical is exhausted until the chemical reaches the minimum residual level L, in order to process the substrate being processed in the chamber 400 without system down, it is preferable to set the MR corresponding to a higher water level than other tanks to the preset water level for the third tank 630.

The controller 30 may control valves installed in the respective drain lines 629 so that the chemical is drained when the water levels of the tank 610, 620, and 630 reach the preset water levels.

As described above, the maintenance method for the chemical supply apparatus may minimize the chemical immediately discarded from the tank by discarding the chemical without recovering the chemical through the chemical exhaustion mode, and sequentially exhausting the chemical of each tank to a preset level and then draining the chemical.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1-8. (canceled)

9. A maintenance method for a liquid treating apparatus including a first tank in which a chemical used in a substrate processing apparatus is recovered, a second tank for receiving the chemical from the first tank, and a third tank for receiving the chemical from the second tank and supplying the chemical to the substrate processing apparatus, the maintenance method comprising:
a chemical exhaustion operation of stopping a supply of a new undiluted liquid from a chemical supply source for a set time before a liquid exchange of the first tank, the second tank, and the third tank proceeds, and exhausting and then draining the chemicals in the first tank, the second tank, and the third tank;
a flushing operation of draining a flushing chemical after injecting and then circulating the flushing chemical into the first tank, the second tank, and the third tank; and
a liquid exchange operation of supplying a new chemical to at least one of the first tank, the second tank, and the third tank and exchanging liquids.

10. The maintenance method of claim 9, wherein in the chemical exhaustion operation, all of the chemical used in the substrate processing apparatus is treated as wastewater without being recovered to the first tank.

11. The maintenance method of claim 10, wherein in the chemical exhaustion operation, the third tank is replenished with the chemical until the chemical of the second tank reaches a minimum residual level, and when the chemical of the second tank reaches the minimum residual level, the replenishment of the third tank with the chemical is stopped, and a remaining chemical of the second tank is drained.

12. The maintenance method of claim 11, wherein in the chemical exhaustion operation, when the chemical of the third tank falls to or below a maximum residual level, the third tank is replenished with the chemical from the second tank, and when the chemical of the second tank reaches the minimum residual level, the replenishment of the third tank with the chemical from the second tank is stopped.

13. The maintenance method of claim 12, wherein in the chemical exhaustion operation, when the chemical in the third tank reaches a preset level, the third tank is switched to a standby state to stop the supply of the chemical to the substrate processing apparatus.

14. The maintenance method of claim 13, wherein the preset level in the third tank is between the minimum residual level and the maximum residual level.

15. The maintenance method of claim 13, wherein in the chemical exhaustion operation, when the chemical of the third tank reaches the preset level, the remaining chemical of the third tank is drained.

16. The maintenance method of claim 10, wherein in the chemical exhaustion operation, the chemical is supplied to the second tank until the chemical of the first tank reaches a minimum residual level.

17. The maintenance method of claim 16, wherein in the chemical exhaustion operation, when the chemical of the first tank reaches the minimum residual level, the remaining chemical of the first tank is drained.

18-20. (canceled)
